(19) United States
(12) Patent Application Publication
(10) Pub. No.: US 2011/0200077 A1
(43) Pub. Date: Aug. 18, 2011

(54) DELTA-SIGMA MODULATOR AND WIRELESS COMMUNICATION DEVICE

(75) Inventors: Yosuke MITANI, Osaka (JP); Kazuo Matsukawa, Osaka (JP); Masao Takayama, Osaka (JP); Shiro Dosho, Osaka (JP)

(73) Assignee: PANASONIC CORPORATION, Osaka (JP)

(21) Appl. No.: 13/094,519

(22) Filed: Apr. 26, 2011

Related U.S. Application Data
(63) Continuation of application No. PCT/JP2009/001714, filed on Apr. 14, 2009.

(30) Foreign Application Priority Data
Nov. 20, 2008 (JP) 2008-296916

(51) Int. Cl. H04B 1/38; H03M 3/02

(52) U.S. Cl. 375/219; 341/143

(57) ABSTRACT

In a DSM including a loop in which an output signal of a quantizer is digitally processed, and fed back through a DAC to an analog filter, the quantizer quantizes an analog signal from an analog filter section to output a digital signal. The digital signal from the quantizer is digitally processed in a first-order recursive filter circuit including a variable gain amplifier and a delay element. A LUT receives both the digital signal from the quantizer and a table control signal, which is an output signal from the recursive filter circuit, and stores in advance compensation values corresponding to the both signals. A compensation value from the LUT is used to provide a digital output signal compensated for a delay. The digital output signal is converted into an analog signal in the DAC, and then subtracted from an analog input signal in the analog filter section.

### CROSS-REFERENCE TO RELATED APPLICATION

This is a continuation of PCT International Application PCT/JP2009/001714 filed on Apr. 14, 2009, which claims priority to Japanese Patent Application No. 2008-296916 filed on Nov. 20, 2008. The disclosures of these applications including the specifications, the drawings, and the claims are hereby incorporated by reference in its entirety.

### BACKGROUND

The present invention relates to delta-sigma modulators (DSMs) and wireless communication devices using the DSMs.

In general, for example as described in Non-Patent Document 1, a DSM used in an analog-to-digital converter (ADC) is known as a means for achieving higher accuracy and lower power consumption in comparison with a Nyquist ADC by a noise-shaping technique and an oversampling technique.

In addition, well-known suitable technologies for a high-speed, wide-bandwidth DSM include continuous-time DSMs described in Non-Patent Documents 1 and 2.

An example of these basic continuous-time DSMs will now be described. FIG. 11 is a block diagram illustrating a schematic configuration of a continuous-time DSM.

The continuous-time DSM shown in FIG. 11 includes a loop filter 502 having an arbitrary frequency characteristic; a quantizer 503 which quantizes an output signal of the loop filter 502, and outputs the result as a digital output signal; a digital-to-analog converter (DAC) 504 which converts the output signal of the quantizer 503 into an analog value, and feeds back the analog value; and a subtracter 501 which calculates the difference between the analog value output from the DAC 504 and an analog input signal. The output of the subtracter 501 is input to the loop filter 502.

FIG. 12 is a block diagram illustrating a linear model of the continuous-time DSM described above. In FIG. 12, assuming that H(s) represents the transfer function of a loop filter 602, an adder 603 having quantization noise E represents the quantizer 503 of FIG. 11, and a transfer function DAC(s) represents the step response of a DAC 605, the transfer function to express the relationship between an analog input signal X and a digital output signal Y can be expressed by Equation 1 shown below. In general, the term associated with the quantization noise E is known as noise transfer function (NTF), and the term associated with the analog input signal X is known as signal transfer function (STF).

$$Y = \frac{H ( s )}{1 + DAC ( s ) H ( s )} X + \frac{1}{1 + DAC ( s ) H ( s )} E \qquad ( Equation 1 )$$

Here, processing of a high-speed signal causes a delay to be introduced to a signal in the feedback path from the output of the quantizer to the loop filter due to both an output delay within the quantizer and a delay caused by switching time of the DAC. Therefore, the noise transfer function NTF and the signal transfer function STF are altered.

Such alteration in the transfer functions of the feedback path means that an error occurs in the amount of charge obtained by an integration by an analog integrator included in the loop filter 502. As a result, the stability is significantly affected, thereby causing problems such as decrease in accuracy of the output signal and oscillation. This delay is generally called “excess loop delay.”

Examples of methods for addressing the decrease in stability and the decrease in accuracy of the output signal due to such an excess loop delay include those which have been described in Patent Documents 2 and 3 and Non-Patent Documents 3 and 4. In these documents, a signal obtained by performing digital-to-analog conversion on an output signal of a quantizer is fed back to the input stage of the quantizer, and the difference from the output signal of the loop filter (analog filter section) is used as an input signal of the quantizer, thereby allowing a transfer function having a decreased stability due to a delay to be converted into a stable transfer function.

However, the conventional methods described in Patent Documents 2 and 3 and Non-Patent Documents 3 and 4 each additionally requires a DAC for feeding back the signal to the input stage of the quantizer. A problem exists in that, in order to settle the feedback signal in the input stage of the quantizer, an operational amplifier having a high gain bandwidth is required, and thus both the power consumption and cost increase.

In addition, since the difference from the output signal of the analog filter section is subtracted in the input stage of the quantizer, the input amplitude to the quantizer is reduced. Thus, the input range of the quantizer is reduced, and the DSM becomes more susceptible to an offset of the quantizer and to manufacturing variation. Therefore, a problem of decrease in accuracy arises.

In order to address these problems, Patent Document 1 has described an example of a method for addressing an excess loop delay without need for an additional DAC. Specifically, in this method, an output signal of the quantizer is passed through a digital modulation loop circuit, and then through a DAC, and is fed back to a part of an analog filter section.

The above-referenced Patent Documents and Non-Patent Documents are as follows:
Patent Document 1: U.S. Patent Application Publication No. 2005/0068213
Patent Document 2: Japanese Patent Publication No. P3362718
Patent Document 3: U.S. Pat. No. 6,414,615
Non-Patent Document 1: Steven R. Norsworthy, Richard Schereier and Gabor C. Temes, “Delta-Sigma Data Converters Theory, Design and Simulation,” IEEE press 1997.
Non-Patent Document 2: H. Inose and Y. Yasuda, “A Unity Bit Coding Method by Negative Feedback,” Proceedings of the IEEE, November, 1963.
Non-Patent Document 3: W. Gao, O. Shoaei and W. M. Snelgrove, “Excess Loop Delay Effects in Continuous-Time Delta-Sigma Modulators and the Compensation Solution,” in Proc. IEEE ISCAS, vol. 1, pp. 65-68, 1997.
Non-Patent Document 4: P. Benabes, M. Keramat and R. Kielbasa, “A Methodology for Designing Continuous-Time Sigma-Delta Modulators,” in Proc. European Design and Test Conf, pp. 46-50, 1997.

### SUMMARY

However, the method described in Patent Document 1 listed above has problems such as the following:

1. A problem exists in that a decrease in the stability due to intrinsic delays in the digital modulation loop is likely to cause abnormal oscillation. In addition, in the configuration described in Patent Document 1, an operation is performed on the output of the quantizer by the digital modulation loop, and the output obtained by this operation is directly input to the DAC. In such a configuration, if, for example, a technique for reducing the effect of manufacturing variation such as dynamic element matching (DEM) is additionally used in a plurality of DAC sections, then the excess loop delay increases, and as a result, the accuracy and the stability decrease.

2. Since the configuration of the digital modulation loop is not apparent, an attempt to achieve an arbitrary feedback gain by the configuration described in Patent Document 1 results in a more complex operation process, thereby requiring a large-scale operation circuit. This is impractical. Although one solution is to round the numbers or to truncate the numbers after the decimal point, the results would be different from expected gains; therefore, a quantization error arising therefrom causes the accuracy and the stability to decrease.

In view of the foregoing, an object of the present invention is to provide a DSM which reduces the effect of a delay and improves the accuracy of an output signal with respect to a high-speed, wide-bandwidth signal, and to provide a wireless communication device using the DSM.

In order to achieve the above object, the present invention adopts, for a DSM requiring no additional DACs, a configuration in which a digital filter is additionally provided such as a recursive filter which, when the transfer function of the loop filter is altered due to a delay, compensates for the delay and changes the transfer function to a same one as the initial transfer function, and appropriate values of the digital output signal causing no delays corresponding to the output of the digital filter and to the digital output of the quantizer are stored in advance in a table. Thus, the amount of delay in the digital modulation filter is reduced, and thus a decrease in the stability of the DSM due to an excess loop delay is reduced.

That is, a DSM according to the present invention includes an analog filter, a quantizer configured to convert an output of the analog filter into a digital signal, and to output the digital signal as a first digital signal, a digital filter configured to perform predetermined digital processing on the first digital signal from the quantizer, and to output a result of the processing as a table control signal, a table storing in advance a second digital signal corresponding to the first digital signal from the quantizer and to the table control signal from the digital filter, a DAC configured to convert the second digital signal from the table into an analog feedback signal, and a subtracter configured to subtract from an input analog signal to the output signal of the DAC, and to output a signal of a result of the subtraction to the analog filter.

A DSM according to the present invention includes an analog filter, a quantizer configured to convert an output of the analog filter into a digital signal, and to output the digital signal as a first digital signal, a digital filter configured to perform predetermined digital processing on the first digital signal from the quantizer, and to output a result of the processing as a first table control signal, a DEM address generator configured to generate a DAC selection signal based on the first table control signal from the digital filter, a table storing in advance a second digital signal corresponding to the first digital signal from the quantizer, to the first table control signal from the digital filter, and to the DAC selection signal from the DEM address generator, a DAC configured to convert the second digital signal from the table into an analog feedback signal, and a subtracter configured to subtract from an input analog signal to the output signal of the DAC, and to output a signal of a result of the subtraction to the analog filter.

In the DSM according to the present invention, the table may include an adjustment means configured to adjust an output gain of the table.

In the DSM according to the present invention, the digital filter may be a recursive filter circuit of an arbitrary order.

A wireless communication device according to the present invention includes a receiver having the DSM, a transmitter configured to modulate a signal for transmission, an antenna, and a transmission-reception switching section configured to switch between supplying a signal for transmission from the transmitter to the antenna and supplying a received signal from the antenna to the receiver.

Thus, in a DSM according to the present invention, a table stores in advance a compensation value (second digital signal) for maintaining the transfer function of the analog filter even when an excess loop delay has been introduced, based on the digital signal from the quantizer, and on the table control signal, which is a result of performing digital processing on the digital signal from the quantizer by the digital filter such as a recursive filter circuit of an arbitrary order. Therefore, the amount of delay of the signal in the feedback path can be reduced, and as a result, a decrease in the stability of the DSM due to an excess loop delay can be reduced, and a decrease in accuracy of the output signal can be avoided. In addition, storing in advance a compensation value in the table allows a suitable compensation value to be output without performing an operation each time, and thus a small-scale circuit can be achieved.

In particular, even when a DEM circuit is used, the present invention reduces the amount of delay of the signal in the feedback path, thereby allowing a decrease in the stability of the DSM due to an excess loop delay to be reduced.

In addition, the present invention provides a wireless communication device in which the quality of a received signal is maintained even for a high-speed, wide-bandwidth signal.

As described above, according to the present invention, the amount of delay of the signal in the feedback path can be reduced, and as a result, the present invention offers advantages in that a decrease in the stability of the DSM due to an excess loop delay can be reduced, and that a decrease in accuracy of the output signal can be avoided.

### BRIEF DESCRIPTION OF THE DRAWINGS

FIG. 1 is a block diagram illustrating a configuration of a DSM according to the first embodiment of the present invention.

FIG. 2 is a diagram illustrating a specific example of the LUT included in the DSM.

FIG. 3 is a diagram illustrating a connection arrangement between the quantizer, the correction signal generator, and the DAC.

FIG. 4 is a diagram illustrating a specific example of the quantizer, of the correction signal generator, and of the DAC.

FIG. 5 is a block diagram illustrating a configuration of a DSM according to the second embodiment of the present invention.

FIG. 6 is a block diagram illustrating a configuration of a DSM according to the third embodiment of the present invention.

FIG. 7 is a diagram illustrating a specific example of the LUT included in the DSM.

FIG. 8 is a diagram for illustrating an operation model of a DEM.

FIG. 9 is a block diagram illustrating a configuration of a wireless communication device according to the fourth embodiment of the present invention.

FIG. 10 is a block diagram illustrating a configuration of a wireless communication device according to the fifth embodiment of the present invention.

FIG. 11 is a block diagram illustrating a configuration of a conventional DSM.

FIG. 12 is a diagram illustrating a linear model for describing the transfer function of a conventional DSM.

### DETAILED DESCRIPTION

Example embodiments of the present invention will be described below with reference to the drawings.

### First Embodiment

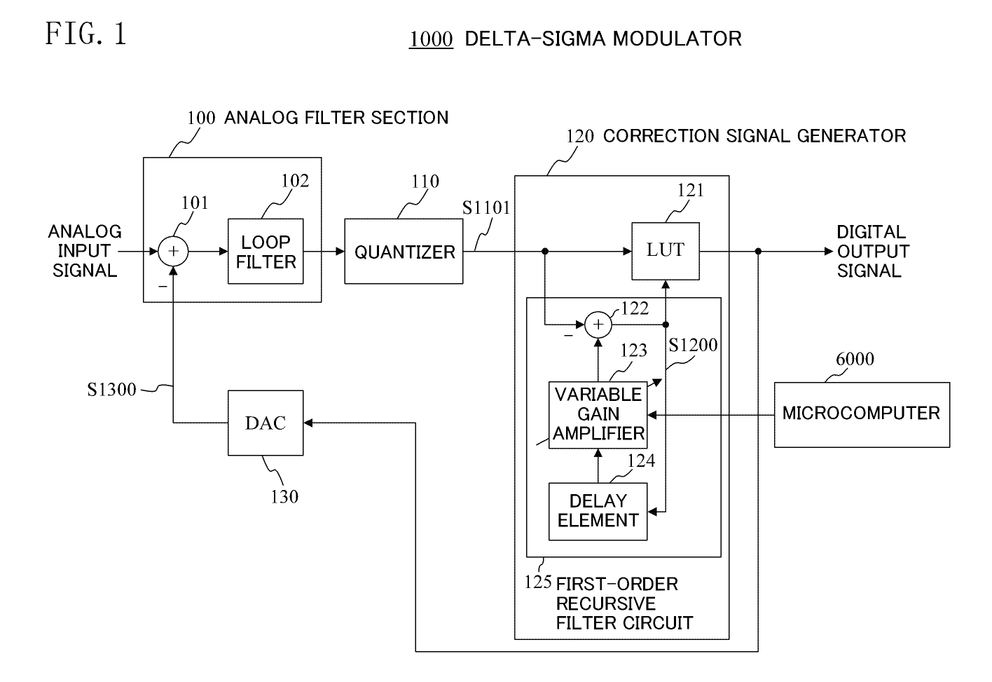

FIG. 1 is a block diagram illustrating a configuration of a delta-sigma modulator (DSM) 1000 according to the first embodiment of the present invention.

As shown in FIG. 1, the DSM includes an analog filter section 100 which allows a particular frequency range to pass, a quantizer 110 which quantizes an analog signal to a digital signal, a correction signal generator 120 which generates a digital output signal corrected based on the digital signal S1101 from the quantizer 110, and a digital-to-analog converter (DAC) 130 with any number of bits which receives the digital output signal output from the correction signal generator 120 as an analog feedback signal, performs digital-to analog conversion on the analog feedback signal, and outputs an analog signal S1300 to the analog filter section 100.

The analog filter section 100 includes a subtracter 101 which subtracts the feedback signal S1300 from the DAC 130 from an analog input signal, and then outputs the result; and a loop filter (analog filter) 102.

The correction signal generator 120 includes a LUT (table) 121, a subtracter 122, a variable gain amplifier 123, and a delay element 124. The subtracter 122, the variable gain amplifier 123, and the delay element 124 form a first-order recursive filter circuit (digital filter) 125. The subtracter 122 subtracts an output signal from the variable gain amplifier 123 from the digital signal S1101 output from the quantizer 110, and outputs the subtraction result as a LUT control signal (table control signal) S1200 to the LUT 121; the delay element 124 delays the LUT control signal S1200 output from the subtracter 122, and outputs the delayed signal; and the variable gain amplifier 123 applies a particular gain to the signal output from the delay element 124, and outputs the resultant signal. The particular gain of the variable gain amplifier 123 is controlled by an external microcomputer (CPU) 6000.

The principle of correction using the first-order recursive filter circuit 125 will now be described. First, a loop filter in which a delay is already taken into account is made so that the transfer function will not be altered even when an excess loop delay is introduced.

The procedure is as follows. First, delaying the transfer function H(z) of the loop filter 102 by one clock cycle yields a transfer function H(z)·Z⁻¹.

Next, the initial transfer function H(z) is altered to satisfy the relationship of Equation 2 shown below so that one clock cycle of delay yields a same transfer function as the initial transfer function, using H(z)′ to represent the altered transfer function.

(H(z)′+α)·z⁻¹=H(z) (Equation 2)

The loop filter H(z)′ generated as shown above provides almost the same transfer function as the initial transfer function H(z) even when a delay z⁻¹ is introduced, by adding a correction factor α. A specific example of these transfer functions will be described using a third-order loop filter.

Assuming that the transfer function of the third-order loop filter is expressed by

Equation 3 shown below, the transfer function H(z)′ satisfying Equation 2 shown above is written as Equation 4 shown below.

$$\begin{matrix}H ( z ) = \frac{1.316 {z}^{2} - 1.904 z + 0.7537}{{z}^{3} - 2.974 {z}^{2} + 2.974 z - 1} & ( Equation 3 ) \\ {H ( z )}^{′} = \frac{1.036 {z}^{2} - 1.776 z + 0.7861}{{z}^{3} - 2.974 {z}^{2} + 2.974 z - 1} & ( Equation 4 )\end{matrix}$$

These transfer functions can be achieved by an actual circuit by adding a path having a gain of α to the feedback path. The transfer function of this part will be one such as Equation 5 shown below by way of example of a first-order filter. This is a transfer function of a first-order recursive filter.

$$\frac{Y}{X} = \frac{1}{α \cdot {z}^{- 1} + 1} \qquad ( Equation 5 )$$

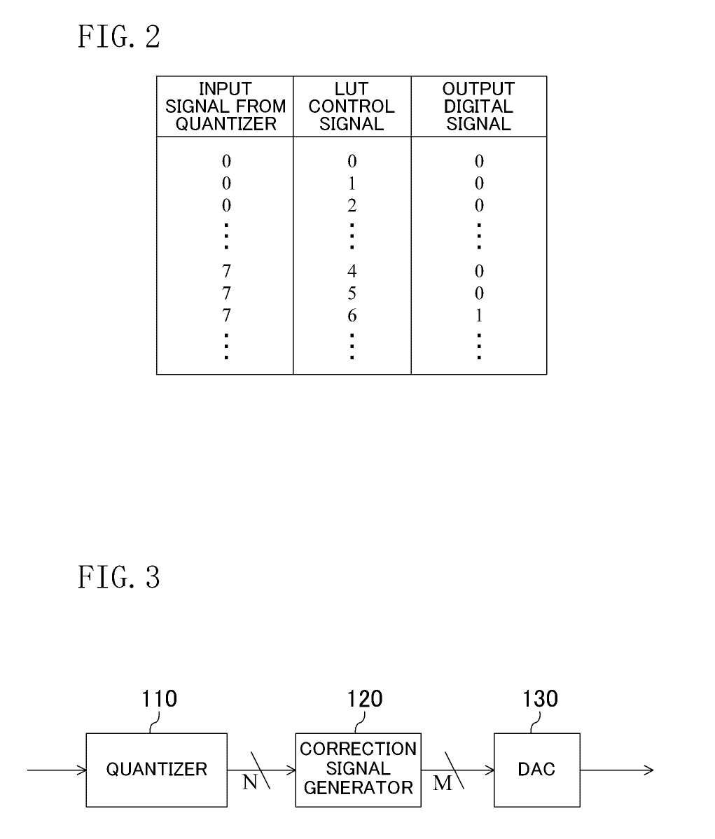

Returning to FIG. 1, the LUT 121 receives both the digital signal (first digital signal) S1101 output from the quantizer 110 and the LUT control signal S1200 output from the subtracter 122. As shown in FIG. 2, the LUT 121 stores in advance the values of the output digital signal corresponding to the values of both the digital signal S1101 from the quantizer 110 and the LUT control signal S1200 from the subtracter 122. Assuming that X represents the input digital signal to the LUT 121, Y represents the output signal from the LUT 121, “a” represents the gain of the variable gain amplifier 123, and “k” represents the gain of the LUT 121, the output digital signal has a relationship allowing the transfer function of Equation 6 shown below.

$$\frac{Y}{X} = \frac{k}{{az}^{- 1} + 1} \qquad ( Equation 6 )$$

The transfer function expressed by Equation 6 is added as the transfer function of the return path of the DSM. The output digital signal Y from the LUT 121 is the correction digital signal (second digital signal), and is the digital output signal of the DSM 1000.

Next, the operation of the DSM 1000 according to the first embodiment will be described.

As described above, the digital output signal generated by the correction signal generator 120 based on the digital signal S1101 output from the quantizer 110 is input to the DAC 130 in the return section. During this process, the LUT control signal S1200 is output as a digital signal obtained by performing an operation called first-order recursive filtering on the signal output from the quantizer 110.

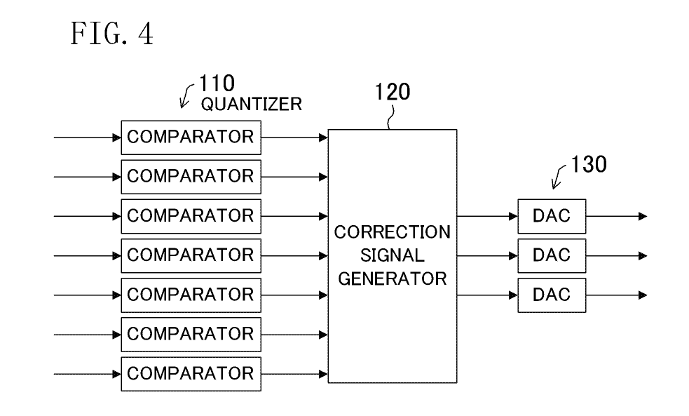

In addition, the LUT 121 stores data (adjustment means) for selecting and outputting an arbitrary bit width in order to adjust the gain of the output signal S1101 from the quantizer 110. This data is the factor k of Equation 6 shown above. For example, if the entire configuration including the correction signal generator 120 including the LUT 121, the quantizer 110, and the DAC 130 provides the transfer function of Equation 6 shown above, then as shown in FIGS. 3 and 4, the LUT 121 of the correction signal generator 120 selects the factor k=M/N, where the resolution of the quantizer 110 is N bits, and the resolution of the DAC is M bits. Using this LUT 121, the correction signal generator 120 determines a transfer function which corresponds to the correction with respect to the excess loop delay. Thus, storing the correspondence between the values which achieve an optimum transfer function in the correction signal generator 120 which is provided between the quantizer 110 and the DAC 130 allows errors to be minimized.

In addition, since the LUT 121 stores compensation values calculated in advance, the output signal can be obtained without need to calculate each time, and the DSM can be implemented by a small-scale circuit.

Thus, according to this embodiment, the additional amount of delay due to a process of generating a correction signal for an excess loop delay can be minimized, and thus the accuracy of the output signal can be maintained even for a high-speed, wide-bandwidth signal.

Moreover, since the LUT 121 may be formed using an SRAM, information therein can be changed. Thus, changing as required the contents of the LUT 121 based on a variation of the amount of delay allows the accuracy of the output signal to be maintained.

### Second Embodiment

Next, the second embodiment of the present invention will be described with reference to the drawings.

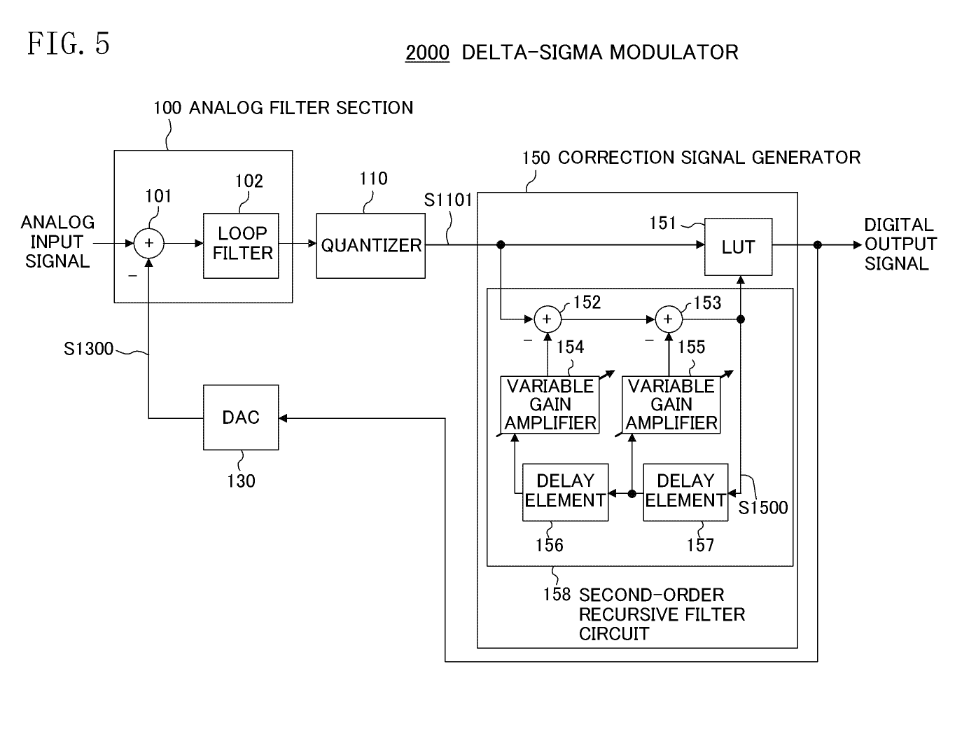

FIG. 5 is a block diagram illustrating a configuration of a DSM 2000 according to the second embodiment of the present invention.

In the second embodiment of the present invention, the same reference characters as those used for the first embodiment of the present invention are used to represent equivalent elements, and the explanation thereof will be omitted.

As shown in FIG. 5, the DSM 2000 according to the second embodiment is different from the DSM 1000 according to the first embodiment of the present invention in that the LUT control signal S1500 in the correction signal generator 150 is generated in a second-order recursive filter 158.

The correction signal generator 150 includes a LUT 151, two subtracters 152 and 153, two delay elements 156 and 157, and two variable gain amplifiers 154 and 155.

The first delay element 157 delays the LUT control signal S1500 output from the second subtracter 153, and outputs the delayed signal. The first variable gain amplifier 155 applies a particular gain to the signal output from the first delay element 157, and outputs the resultant signal. In addition, the second delay element 156 delays the signal output from the first delay element 157, and outputs the delayed signal. The second variable gain amplifier 154 applies a particular gain to the signal output from the second delay element 156, and outputs the resultant signal. The first subtracter 152 subtracts the difference between the digital signal S1101 output from the quantizer 110 and the output signal of the second variable gain amplifier 154, and outputs the subtraction result. The second subtracter 153 subtracts the output from the first variable gain amplifier 155 from the output signal of the first subtracter 152, and outputs the subtraction result to the LUT 151 and to the first delay element 157 as the LUT control signal S1500.

Although not shown, the LUT 151 stores in advance, similarly to the case in the first embodiment, the values of the output digital signal corresponding to the values of both the digital signal S1101 output from the quantizer 110 and the LUT control signal S1500 output from the second subtracter 153, and outputs an output digital signal corresponding to the both signals. Assuming that X represents the input digital signal to the LUT 151, Y represents the output digital signal from the LUT 151, “a” represents the gain of the second variable gain amplifier 154, “b” represents the gain of the first variable gain amplifier 155, and “k” represents the gain of the LUT 151, the output digital signal has a relationship allowing the transfer function of Equation 7 shown below.

$$\frac{Y}{X} = \frac{k}{{az}^{- 2} + {bz}^{- 1} + 1} \qquad ( Equation 7 )$$

The transfer function expressed by Equation 7 is added as the transfer function of the return path of the DSM.

Thus, in this embodiment, since the LUT control signal S1500 in the correction signal generator 150 is generated in the second-order recursive filter 158, quantization errors can be further reduced in comparison with a case of a first-order recursive filter.

### Third Embodiment

Next, the third embodiment of the present invention will be described with reference to the drawings.

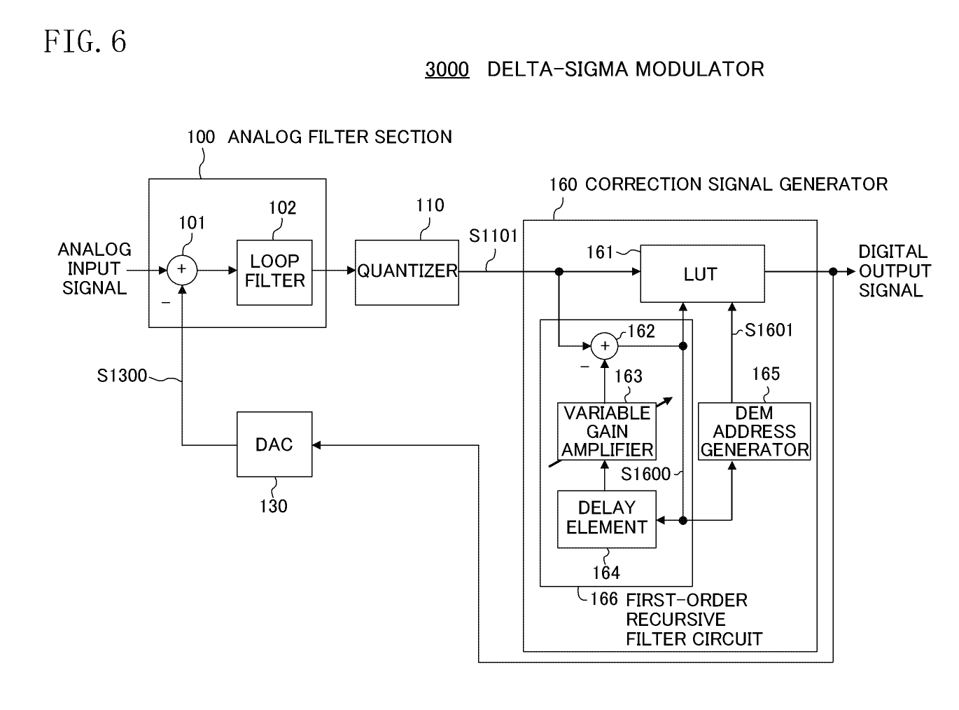

FIG. 6 is a block diagram illustrating a configuration of a DSM 3000 according to the third embodiment of the present invention.

As shown in FIG. 6, the DSM 3000 according to the third embodiment of the present invention is different from the DSM 1000 according to the first embodiment in that a DEM address generator 165 is added in the correction signal generator.

The operation of DEM for the DAC 130 having a DEM mechanism will now be described. If there is device-to-device variation in a multiple-bit DAC, the output signal will be distorted, thereby causing the signal-to-noise ratio (SNR) to be decreased. In such a case, a DEM mechanism is generally used as a technique to compensate for the device-to-device variation in the DAC. Here, a technique called data weighted averaging (DWA), which is a typical DEM algorithm, will be described. The DWA technique balances the usage of the devices by sequentially selecting the plurality of DAC devices included in the DAC 130. For example, assuming that a DEM control signal has three bits and seven DAC devices are arranged in a circle as shown in FIG. 8, a first control signal to the DAC of “4” would cause the DAC devices 1, 2, 3, and 4 to be selected, and then a next control signal of “5” would cause the DAC devices 5, 6, 7, 1, and 2 to be selected. In this way, all the DAC devices are sequentially selected to balance the usage of the DAC devices.

In FIG. 6, the correction signal generator 160 includes a LUT 161, a subtracter 162, a variable gain amplifier 163, a delay element 164, and a DEM address generator 165. Similarly to the case in the first embodiment, the subtracter 162, the variable gain amplifier 163, and the delay element 164 form a first-order recursive filter circuit (digital filter) 166. The DEM address generator 165 receives a LUT control signal (first table control signal) S1600 from the subtracter 162, and outputs a DEM address control signal S1601 based on the LUT control signal.

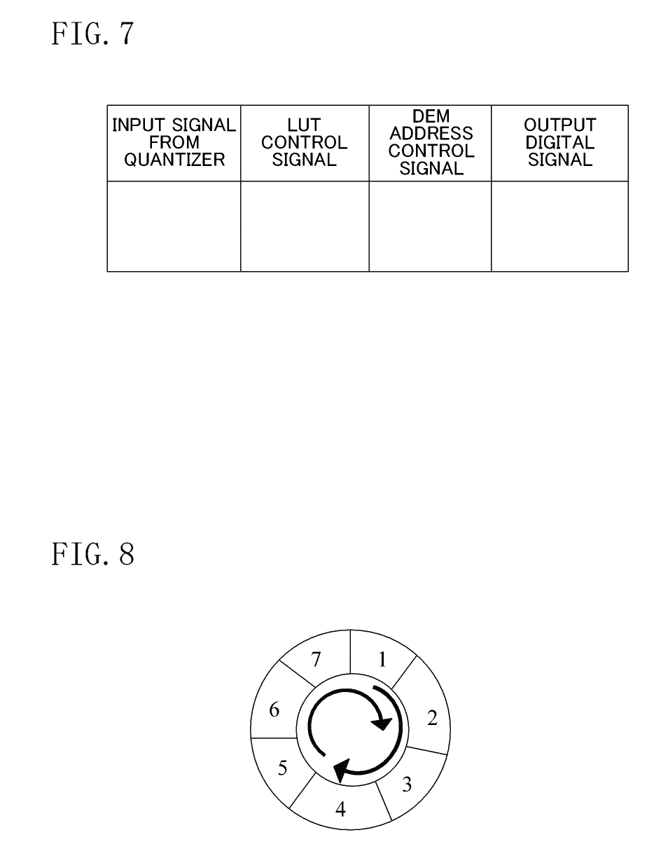

The LUT 161 receives the digital signal (first digital signal) S1101 output from the quantizer 110, the LUT control signal (first table control signal) S1600 output from the subtracter 162, and the DEM address control signal (DAC selection signal) S1601 from the DEM address generator 165. As shown FIG. 7, the LUT 161 stores in advance the values of an output digital signal (second digital signal) corresponding to the values of the digital input signal from the quantizer 110, the LUT control signal S1600 from the subtracter 162, and the DEM address control signal (DAC selection signal) S1601 from the DEM address generator 165. Assuming that X represents the input digital signal to the LUT 161, Y represents the output digital signal from the LUT 161, “a” represents the gain of the variable gain amplifier 163, and “k” represents the gain of the LUT 161, the output digital signal has a relationship allowing the transfer function of Equation 6 shown above.

Next, the operation of the DSM 3000 according to the third embodiment will be described.

In the third embodiment, the number of DAC devices in the DAC 130 driven by the digital output signal output from the LUT 161 does not change itself, and thus the total of the fed back current values is the same, while the positions of driven DAC devices in the DAC 130 change. Therefore, the correction signal generator 160 provides the same transfer function as that of Equation 2 shown above.

Thus, according to this embodiment, the additional amount of delay due to a process of generating a correction signal for an excess loop delay can be minimized also in a configuration in which a DEM mechanism is added in the DAC 130, and thus the accuracy of the output signal can be maintained even for a high-speed, wide-bandwidth signal.

### Fourth Embodiment

Next, the fourth embodiment of the present invention will be described with reference to the drawings.

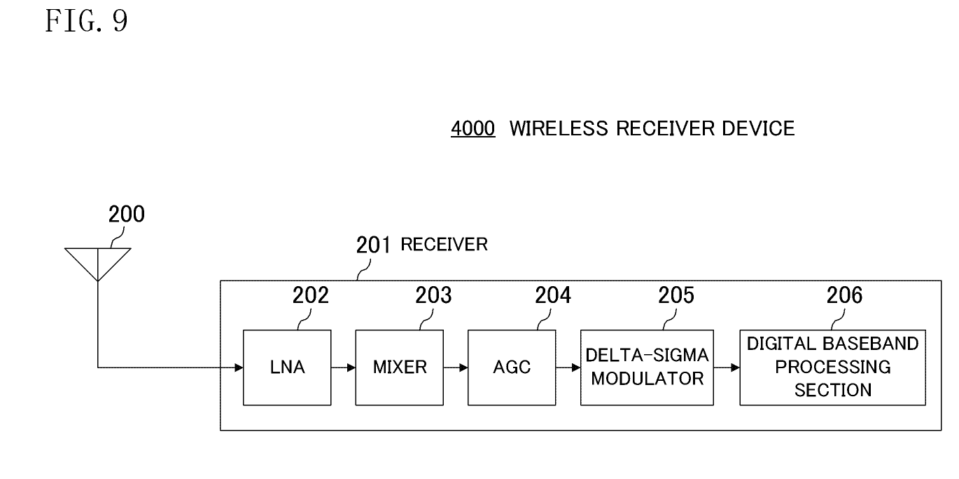

FIG. 9 illustrates a configuration of a wireless receiver device 4000 according to the fourth embodiment of the present invention.

As shown in FIG. 9, the wireless receiver device 4000 according to the fourth embodiment includes a receiver 201 having a DSM 205 according to any one of the first through third embodiments, a low noise amplifier (LNA) 202, a mixer 203, an automatic gain control circuit (AGC) 204, and a digital baseband processor 206; and an antenna 200.

With the configuration described above, a wireless receiver device can be provided in which the accuracy of a wide-bandwidth signal is maintained.

### Fifth Embodiment

Next, the fifth embodiment of the present invention will be described with reference to the drawings.

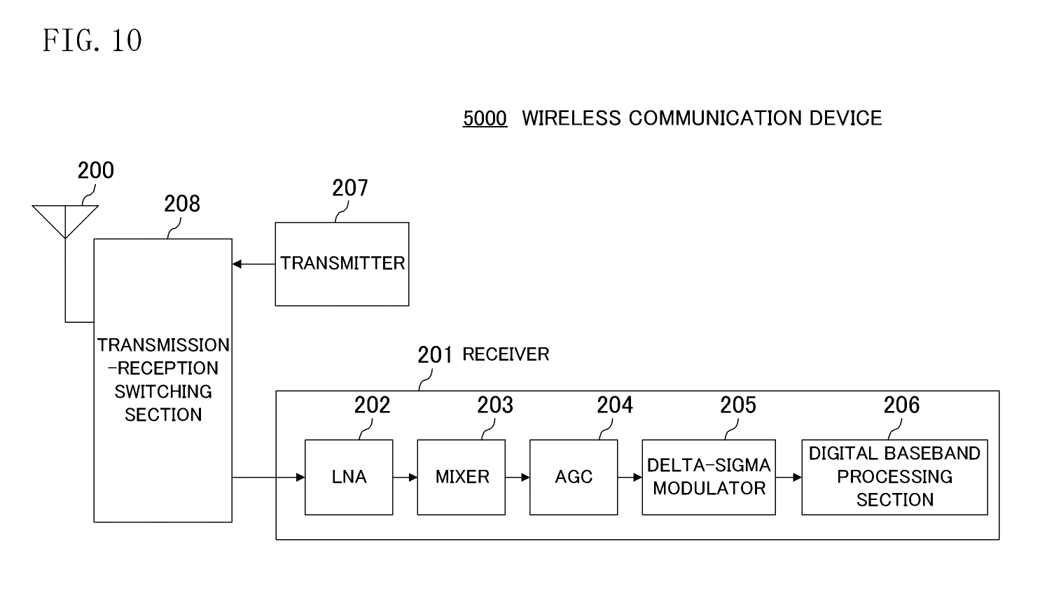

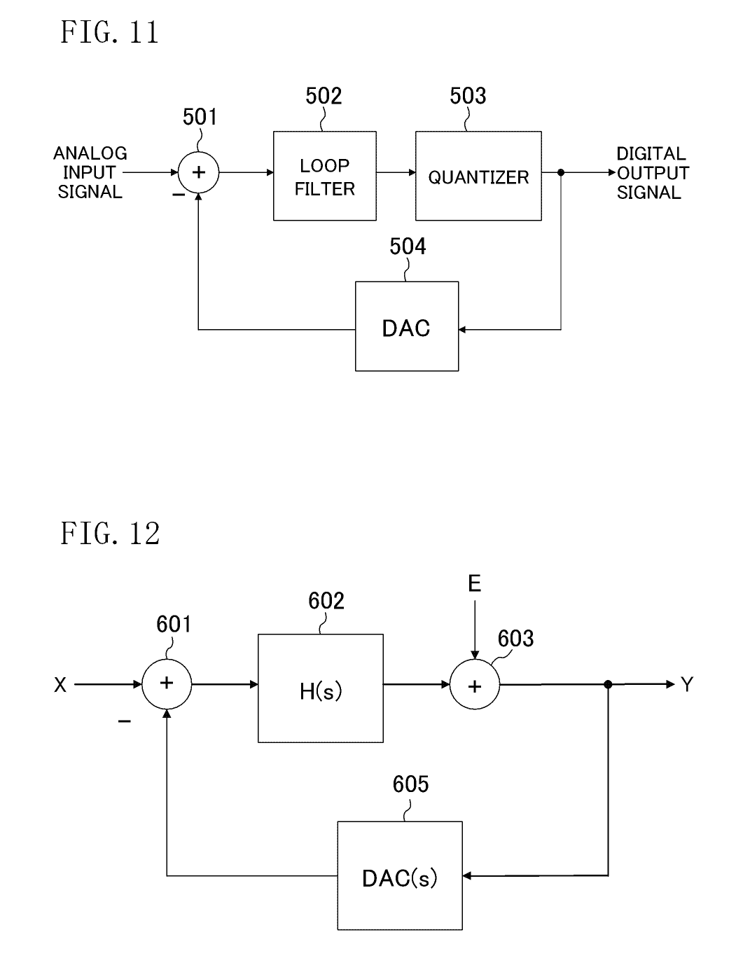

FIG. 10 illustrates a configuration of a wireless communication device 5000 according to the fifth embodiment of the present invention.

As shown in FIG. 10, the wireless communication device 5000 according to the fifth embodiment includes a receiver 201 having a DSM 205 according to any one of the first through third embodiments, a low noise amplifier (LNA) 202, a mixer 203, an automatic gain control circuit (AGC) 204, and a digital baseband processor 206; a transmitter 207 which performs a predetermined transmission process, including a conversion process, on a signal for transmission; a transmission-reception switching section 208 which switches between the signal for transmission and a received signal; and an antenna 200.

With the configuration described above, a wireless communication device can be provided in which the accuracy of a wide-bandwidth signal is maintained. Thus, using the device in, for example, a mobile phone allows voice transmission and reception of high quality.

Although the specific embodiments have been described, the present invention is not limited to the particular configurations with respect to the presented first, second, and third embodiments. For example, the variable gain amplifier 123 of the correction signal generator 120 may be a fixed gain amplifier. In addition, the LUT control signal S1500 in the correction signal generator 150 may be generated by a recursive filtering process of an arbitrary order. Moreover, the DEM address generator 165 may be provided together with a second-order recursive filter circuit, instead of the first-order recursive filter circuit 166.

As described above, the present invention can reduce the amount of delay of the signal in the feedback path, and as a result, reduce a decrease in the stability of the DSM due to an excess loop delay, thereby maintain the accuracy of the output signal for a high-speed, wide-bandwidth signal. Therefore, the present invention is useful for electronic devices such as data conversion circuits, wireless communication devices, audio devices, video devices, etc.

What is claimed is:

1. A delta-sigma modulator (DSM), comprising:
an analog filter;
a quantizer configured to convert an output of the analog filter into a digital signal, and to output the digital signal as a first digital signal;
a digital filter configured to perform predetermined digital processing on the first digital signal from the quantizer, and to output a result of the processing as a table control signal;
a table storing in advance a second digital signal corresponding to the first digital signal from the quantizer and to the table control signal from the digital filter;
a digital-to-analog converter (DAC) configured to convert the second digital signal from the table into an analog feedback signal; and
a subtracter configured to subtract from an input analog signal to the output signal of the DAC, and to output a signal of a result of the subtraction to the analog filter.

2. A DSM, comprising:
an analog filter;
a quantizer configured to convert an output of the analog filter into a digital signal, and to output the digital signal as a first digital signal;
a digital filter configured to perform predetermined digital processing on the first digital signal from the quantizer, and to output a result of the processing as a first table control signal;
a DEM address generator configured to generate a DAC selection signal based on the first table control signal from the digital filter;
a table storing in advance a second digital signal corresponding to the first digital signal from the quantizer, to the first table control signal from the digital filter, and to the DAC selection signal from the DEM address generator;
a DAC configured to convert the second digital signal from the table into an analog feedback signal; and
a subtracter configured to subtract from an input analog signal to the output signal of the DAC, and to output a signal of a result of the subtraction to the analog filter.

3. The DSM of claim 1, wherein
the table includes an adjustment means configured to adjust an output gain of the table.

4. The DSM of claim 1, wherein
the digital filter is a recursive filter circuit of an arbitrary order.

5. A wireless communication device, comprising:
a receiver having the DSM of claim 1;
a transmitter configured to modulate a signal for transmission;
an antenna; and
a transmission-reception switching section configured to switch between supplying the signal for transmission from the transmitter to the antenna and supplying a received signal from the antenna to the receiver.

6. The DSM of claim 2, wherein
the table includes an adjustment means configured to adjust an output gain of the table.

7. The DSM of claim 2, wherein
the digital filter is a recursive filter circuit of an arbitrary order.

8. A wireless communication device, comprising:
a receiver having the DSM of claim 2;
a transmitter configured to modulate a signal for transmission;
an antenna; and
a transmission-reception switching section configured to switch between supplying the signal for transmission from the transmitter to the antenna and supplying a received signal from the antenna to the receiver.
